(19) United States
(12) Patent Application Publication
(10) Pub. No.: US 2015/0155188 A1
(43) Pub. Date: Jun. 4, 2015

(54) SUBSTRATE TREATING APPARATUS AND METHOD

(71) Applicant: SEMES CO., LTD., Chungcheongnam-do (KR)

(72) Inventors: In-II Jung, Chungcheongnam-do (KR); Woo-Young Kim, Chungcheongnam-do (KR); Young il Lee, Chungcheongnam-do (KR); Boong Kim, Chungcheongnam-do (KR)

(21) Appl. No.: 14/556,380

(22) Filed: Dec. 1, 2014

(30) Foreign Application Priority Data
Nov. 29, 2013 (KR) 10-2013-0147467
Jan. 21, 2014 (KR) 10-2014-0007314

(51) Int. Cl. H01L 21/67; B08B 7/00; F26B 21/10; H01J 37/32

(52) U.S. Cl. CPC H01L 21/67023; H01L 21/67034; H01L 21/6704; H01L 21/67075; H01J 37/32449; H01J 37/32798; B08B 7/0021; F26B 21/10; H01J 2237/334; H01J 2237/335

(57) ABSTRACT

Provided is a substrate treating apparatus. The substrate treating apparatus includes a process chamber in which a predetermined process is performed on a substrate, a pressure meter measuring a pressure within the process chamber, and a controller receiving the measured pressure value from the pressure meter to determine an opening time of the process chamber. The controller opens the process chamber when a set condition elapses from a time at which the pressure within the process chamber reaches a preset opening pressure.

### CROSS-REFERENCE TO RELATED APPLICATIONS

This U.S. non-provisional patent application claims priority under 35 U.S.C. §119 of Korean Patent Application Nos. 10-2013-0147467, filed on Nov. 29, 2013, and 10-2014-0007314, filed on Jan. 21, 2014, the entire contents of which are hereby incorporated by reference.

### BACKGROUND OF THE INVENTION

The present invention disclosed herein relates to a substrate treating apparatus and method.

Semiconductor devices are manufactured by forming a circuit pattern on a substrate through various processes such as a photolithography process. In recent years, a supercritical drying process for drying a substrate by using a supercritical fluid is being used for manufacturing a semiconductor device having a line width of about 30 nm or less. The supercritical fluid may represent a fluid having both gas and liquid characteristics under a critical temperature and pressure. The supercritical fluid has superior diffusion and penetration properties and high dissolubility. Thus, since the supercritical fluid has little surface tension, the supercritical fluid may be very usefully used for drying a substrate.

However, the process chamber in which the supercritical process is performed has to be maintained in a high-pressure supercritical state. Accordingly, after the supercritical process is performed under the high-pressure state, when an internal pressure of the process chamber is the same as an external pressure of the process chamber, the process chamber is opened. However, when the process chamber is immediately opened after the external and internal pressures of the process chamber are the same, the process chamber may be opened in a state where residues of carbon dioxide and an organic solvent remaining in the process chamber are not sufficiently exhausted. Thus, the residues of the carbon dioxide and organic solvent may be discharged to the outside of the process chamber through a door. As a result, the residues of the carbon dioxide and organic solvent may contaminate external environments of the process chamber and acts as particles to affect following processes.

### SUMMARY OF THE INVENTION

The present invention provides a substrate treating apparatus that is capable of minimizing back-contamination within a housing.

The object of the present invention is not limited to the aforesaid, but other objects not described herein will be clearly understood by those skilled in the art from descriptions below.

The present invention provides a substrate treating apparatus.

Embodiments of the present invention provide substrate treating apparatuses including: a process chamber in which a predetermined process is performed on a substrate; a pressure meter measuring a pressure within the process chamber; and a controller receiving the measured pressure value from the pressure meter to determine an opening time of the process chamber, wherein the controller opens the process chamber when a set condition elapses from a time at which the pressure within the process chamber reaches a preset opening pressure.

In some embodiments, the predetermined process may include a process for treating the substrate by using a supercritical fluid, and the set condition may be a state in which a set time elapses from the time at which the pressure within the process chamber reaches the preset opening pressure.

In other embodiments, the set time may range from about 1 second to about 60 seconds.

In still other embodiments, the opening pressure may be the same as an atmospheric pressure.

In even other embodiments, the substrate treating apparatuses may further include a first exhaust line for exhausting a gas within the process chamber to the outside of the process chamber.

In yet other embodiments, the substrate treating apparatuses may further include: a second exhaust line branched from the first exhaust line; and a decompression pump disposed on the second exhaust line, wherein the controller may control the decompression pump to discharge the gas within the process chamber from a time at which the pressure within the process chamber reaches the preset opening pressure.

In further embodiments, the controller may open the process chamber when the pressure within the process chamber rises again up to the preset opening pressure after the pressure within the process chamber drops down up to a pressure that is less than the preset opening pressure.

In still further embodiments, the predetermined process may include a process for treating the substrate by using a supercritical fluid, and the set condition may be a state in which the pressure within the second process chamber rises again up to the preset opening pressure after the pressure within the second process chamber drops down up to a pressure that is less than the preset opening pressure.

In even further embodiments, the opening pressure may be the same as an atmospheric pressure.

In yet further embodiments, the substrate treating apparatuses may further include a first exhaust line for exhausting a gas within the process chamber to the outside of the process chamber.

In much further embodiments, the substrate treating apparatuses may further include: a second exhaust line branched from the first exhaust line; and a decompression pump disposed on the second exhaust line, wherein the controller may control the decompression pump to discharge the gas within the process chamber from a time at which the pressure within the process chamber reaches the preset opening pressure.

The present invention provides a substrate treating method.

In other embodiments of the present invention, substrate treating methods include: opening a process chamber after a predetermined process is performed in the process chamber, wherein a pressure within the process chamber is measured to open the process chamber after a set condition elapses from a time at which the pressure within the process chamber reaches a preset opening pressure.

In some embodiments, the predetermined process may include a process for treating the substrate by using a supercritical fluid, and the set condition may be a state in which a set time elapses from the time at which the pressure within the process chamber reaches the preset opening pressure.

In other embodiments, the set time may range from about 1 second to about 60 seconds.

In still other embodiments, the opening pressure may be the same as an atmospheric pressure.

In even other embodiments, when the pressure within the process chamber rises again up to the preset opening pressure after the pressure within the process chamber drops down up to a pressure that is less than the preset opening pressure, the process chamber may be opened.

In yet other embodiments, the predetermined process may include a process for treating the substrate by using a supercritical fluid, and the set condition may be a state in which the pressure within the second process chamber rises again up to the preset opening pressure after the pressure within the second process chamber drops down up to a pressure that is less than the preset opening pressure.

In further embodiments, the opening pressure may be the same as an atmospheric pressure.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a graph illustrating phase change of carbon dioxide;

FIG. 2 is a plan view of the substrate treating apparatus according to an embodiment;

FIG. 3 is a cross-sectional view of a first process chamber of FIG. 2;

FIG. 4 is a cross-sectional view of a second process chamber of FIG. 2 according to an embodiment;

FIG. 5 is a cross-sectional view of a second process chamber of FIG. 4 according to another embodiment;

FIG. 6 is a graph illustrating an example of a set condition;

FIG. 7 is a graph illustrating another example of the set condition;

FIG. 8 is a flowchart of a substrate treating method according to an embodiment; and

FIGS. 9 to 14 are views illustrating an operation process according to the substrate treating method of FIG. 8.

### DETAILED DESCRIPTION OF PREFERRED EMBODIMENTS

The terms used in this specification and the attached drawings are only for easily understanding the present invention, and thus the present invention is not limited to the terms and drawings.

Also, detailed description with respect to well-known technologies that are not directly related to the technical features of the present invention among the technologies used in the present invention will be omitted.

Hereinafter, a substrate treating apparatus 100 according to the present invention will be described.

The substrate treating apparatus 100 may perform a supercritical process for treating a substrate S by using a supercritical fluid as a process fluid.

Here, the substrate S may be understood as comprehensive substrates including substrates used for manufacturing semiconductor devices, flat panel displays (FPDs), and other objects on which a circuit pattern is formed on a thin film. Exemplary examples of the substrate S may include various wafers including silicon wafers, glass substrates, and organic substrates.

A supercritical fluid represents a phase that has gas and liquid properties at the same time when a fluid reaches a supercritical state above its critical pressure and temperature. The supercritical fluid may have molecular density similar to that of a liquid and viscosity similar to that of a gas. Thus, since the supercritical fluid has very superior diffusivity, penetration, and solvency, the supercritical fluid may be advantageous in chemical reaction. In addition, since the supercritical fluid has no surface tension, interfacial tension may not be applied to a fine structure.

The supercritical process is performed by using the properties of the supercritical fluid. Exemplary examples of the supercritical process may include a supercritical drying process and a supercritical etching process. Hereinafter, the supercritical drying process may be described as an example of the supercritical process. However, since this is merely an example for convenience of description, the substrate treating apparatus 100 may perform other supercritical processes in addition to the supercritical drying process.

The supercritical drying process may be performed in a manner in which an organic solvent remaining on a circuit pattern of the substrate S is dissolved by using the supercritical fluid to dry the substrate S. Here, according to this manner, drying efficiency may be superior, and also a collapse phenomenon may be prevented. A material having miscibility with the organic solvent may be used as the supercritical fluid that is used for the supercritical drying process. For example, supercritical carbon dioxide (scCO₂) may be used as the supercritical fluid.

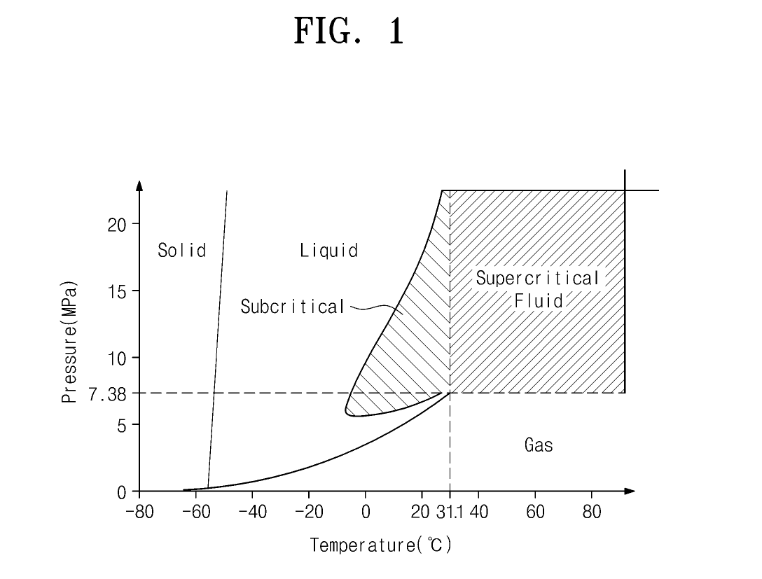

FIG. 1 is a graph illustrating phase change of carbon dioxide.

Carbon dioxide has a relatively low critical temperature of about 31.1° C., and a relatively low critical pressure of about 7.38 Mpa. Thus, since carbon dioxide is easily changed in a supercritical state, and the phase change is easily controlled by adjusting the temperature and pressure, carbon dioxide may be inexpensive. Also, carbon dioxide may be harmless to humans without having toxicity and have nonflammable and inactive properties. In addition, supercritical carbon dioxide may have a high diffusion coefficient that is greater (about 10 times to about 100 times) than that of water or another organic solvent. Thus, since supercritical carbon dioxide is quickly penetrated, easily substituted for the organic solvent, and has little surface tension, supercritical carbon dioxide may have physical properties that are advantageous for drying the substrate S having a fine circuit pattern. In addition, carbon dioxide may be recycled from byproducts generated by various chemical reaction and be converted into a gas phase to separate the organic solvent after the carbon dioxide is used for the supercritical drying process. As a result, the carbon dioxide may be reusable to lighten the burden in aspect of environment contamination.

Hereinafter, a substrate treating apparatus 100 according to an embodiment of the present invention will be described. The substrate treating apparatus 100 according to an embodiment of the present invention may perform a cleaning process in addition to the supercritical drying process.

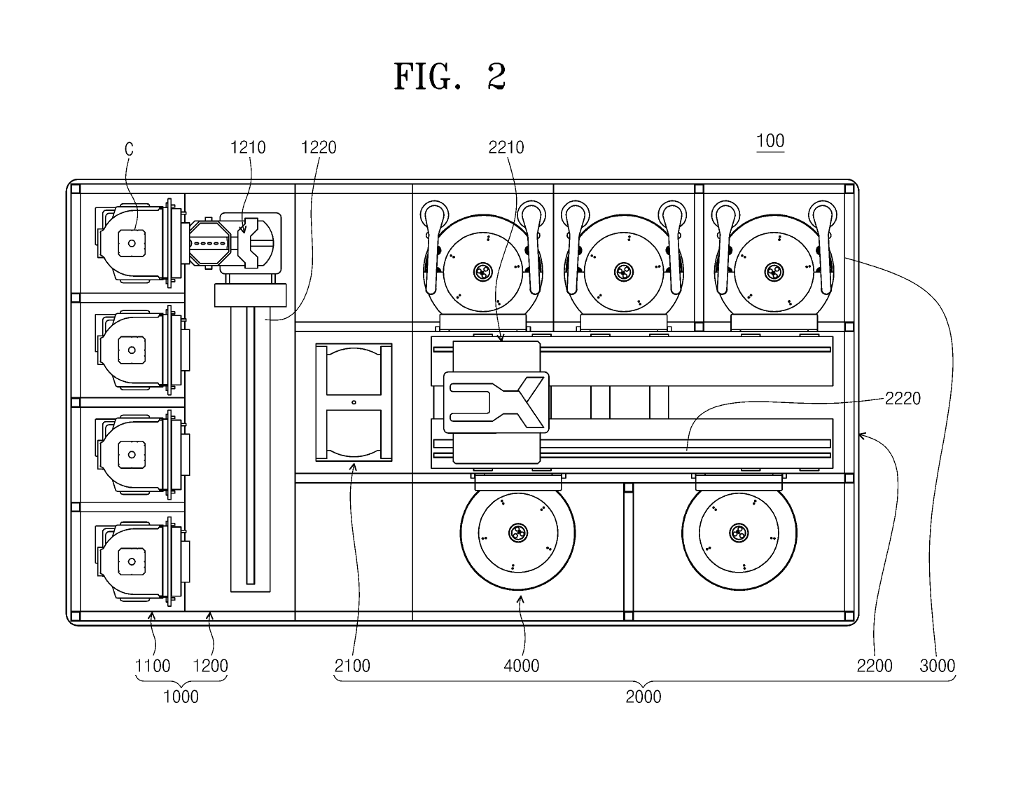

FIG. 2 is a plan view of the substrate treating apparatus 100 according to an embodiment.

Referring to FIG. 2, the substrate treating apparatus 100 includes an index module 1000 and a process module 2000.

The index module 1000 may receive a substrate S from the outside to transfer the substrate S into the process module 2000, and the process module 2000 may perform a supercritical drying process.

The index module 1000 may be an equipment front end module (EFEM) and include a loadport 1100 and a transfer frame 1200.

A container C in which the substrate S is accommodated is placed on the loadport 1100. A front opening unified pod (FOUP) may be used as the container C. The container C may be taken in the loadport 1100 from the outside or taken out of the loadport 1100 by an overhead transfer (OHT).

The transfer frame 1200 transfers the substrate S between the container C placed on the loadport 1100 and the process module 2000. The transfer frame 1200 includes an index robot 1210 and an index rail 1220. The index robot 1210 may transfer the substrate S while moving along the index rail 1220.

The process module 2000 may be a module in which the process is actually performed. The process module 2000 includes a buffer chamber 2100, a transfer chamber 2200, a first process chamber 3000, and a second process chamber 4000.

The buffer chamber 2100 provides a space in which the substrate S to be transferred between the index module 1000 and the process module 2000 temporarily stays. A buffer slot on which the substrate S is placed may be provided in the buffer chamber 2100. For example, the index robot 1210 may take the substrate S out of the container C to place the substrate S on the buffer slot, and the transfer robot 2210 of the transfer chamber 2200 may pick up the substrate S placed on the buffer slot to transfer the substrate S into the first or second process chamber 3000 or 4000. A plurality of buffer slots may be provided in the buffer chamber 2100 to place a plurality of substrates S thereon.

The transfer chamber 2200 transfers the substrate S between the buffer chamber 2100, the first process chamber 3000, and the second process chamber 4000, which are disposed therearound. The transfer chamber 2200 includes a transfer robot 2210 and transfer rail 2220. The transfer robot 2210 may transfer the substrate S while moving along the transfer rail 2220.

The cleaning process may be performed in each of the first and second process chambers 3000 and 4000. Here, the cleaning process may be successively performed in the first and second process chambers 3000 and 4000. For example, a chemical process, a rinsing process, and an organic solvent process of the cleaning process may be performed in the first process chamber 3000, and then, the supercritical drying process may be performed in the second process chamber 4000.

The first and second process chambers 3000 and 4000 are disposed on a side surface of the transfer chamber 2200. Alternatively, the first and second process chambers 3000 and 4000 may be disposed on different side surfaces of the transfer chamber 2200 to face each other.

Also, each of the first process chamber 3000 and the second process chamber 4000 may be provided in plurality in the process module 2000. The plurality of process chambers 3000 and 4000 may be arranged in a line on the side surface of the transfer chamber, be vertically stacked on each other, or be disposed through combination thereof.

The arrangement of the first and second process chambers 3000 and 4000 are not limited to the above-described example. For example, the arrangement of the first and second chambers 3000 and 4000 may variously change in consideration of various factors such as a foot print and process efficiency of the substrate treating apparatus 100.

Hereinafter, the first process chamber 3000 will be described.

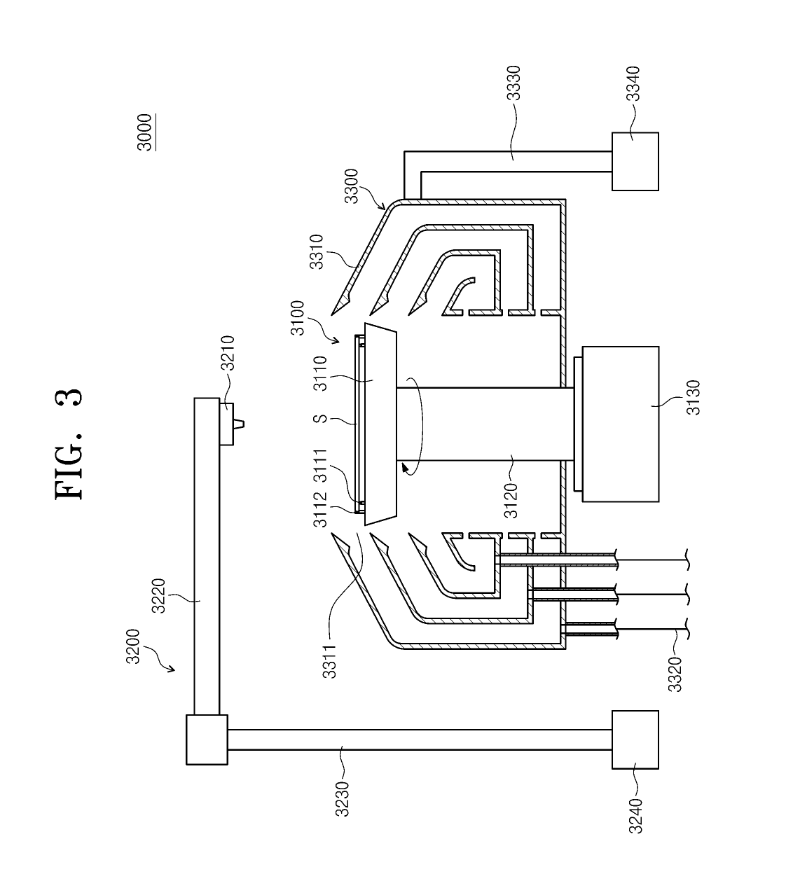

FIG. 3 is a cross-sectional view of the first process chamber 3000 of FIG. 2.

The chemical process, the rinsing process, and the organic solvent process may be performed in the first process chamber 3000. Of course, only a portion of these processes may be selectively performed in the first process chamber 3000. Here, the chemical process may be a process for supplying a cleaning agent onto the substrate S to remove foreign substances from the substrate S, the rinsing process may be a process for supplying a rinsing agent onto the substrate S to clean the cleaning agent remaining on the substrate S, and the organic solvent process may be a process for supplying an organic solvent onto the substrate S to substitute the rinsing agent remaining between circuit pattern of the substrate S for the organic solvent having low surface tension.

Referring to FIG. 3, the first process chamber 3000 includes a support member 3100, a nozzle member 3200, and a collection member 3300.

The support member 3100 may support the substrate S and rotate the supported substrate S. The support member 3100 may include a support plate 3110, a support pin 3111, a chucking pin 3112, a rotation shaft 3120, and a rotation driver 3130.

The support plate 3110 may have a top surface that is equal or similar to that of the substrate S, and the support pin 3111 and the chucking pin 3112 may be disposed on the top surface of the support plate 3110. The support pin 3111 may support the substrate S, and the chucking pin 3112 may fix the supported substrate S.

The rotation shaft 3120 is connected to a lower portion of the support plate 3110. The rotation shaft 3120 may receive a rotation force from the rotation driver 3130 to rotate the support plate 3110. Thus, the substrate S seated on the support plate 3110 may be rotated. Here, the chucking pin 3112 may prevent the substrate S from leaving from its regular position.

The nozzle member 3200 sprays a chemical agent onto the substrate S. The nozzle member 3200 includes a nozzle 3210, a nozzle bar 3220, a nozzle shaft 3230, and a nozzle shaft driver 3240.

The nozzle 3210 sprays the chemical agent onto the substrate S seated on the support plate 3110. The chemical agent may be a cleaning agent, a rinsing agent, or an organic solvent. Here, a hydrogen peroxide (H₂O₂) solution or a solution in which ammonia (NH₄OH), a hydrochloric acid (HCl), or hydrogen peroxide (H₂SO₄) is mixed into a hydrogen peroxide (H₂O₂) solution, or a hydrofluoric acid (HF) solution may be used as the cleaning agent. Also, deionized water may be used as the rinsing agent. Also, isopropyl alcohol, ethyl glycol, 1-propanol, tetra hydraulic franc, 4-hydroxyl, 4-methyl, 2-pentanone, 1-butanol, 2-butanol, methanol, ethanol, n-propyl alcohol, or dimethylether solution or gas may be used as the organic solvent.

The nozzle 3210 may be disposed on a bottom surface of an end of the nozzle bar 3220. The nozzle bar 3220 is coupled to the nozzle shaft 3230, and the nozzle shaft 3230 may be elevated or rotated. The nozzle driver 3240 may elevate or rotate the nozzle shaft 3230 to adjust a position of the nozzle 3210.

The collection member 3300 may collect the chemical agent supplied onto the substrate S. When the chemical agent is supplied onto the substrate S by the nozzle member 3200, the support member 3100 may rotate the substrate S to uniformly supply the chemical agent onto an entire area of the substrate S. When the substrate S is rotated, the chemical agent may be scattered from the substrate S, and the scattered chemical agent may be collected by the collection member 3300.

The collection member 3300 may include a collection box 3310, a collection line 3320, an elevation bar 3330, and an elevation driver 3340.

The collection box 3310 may have an annular ring shape that surrounds the support plate 3110. The collection box 3310 may be provided in plurality. When viewed from above, the plurality of collection boxes 3310 may have ring shapes that are successively away from the support plate 3110. Here, the collection box 3310 that is far away from the support plate 3110 may be disposed at a relatively high height. Thus, a collection hole 3311 through which the chemical agent scattered from the substrate S is introduced may be defined in a space between the collection boxes 3310.

The collection line 3320 is disposed on a bottom surface of the collection box 3310. The collection line 3320 may supply the chemical agent, which is collected into the collection box 3310, into a chemical agent recycling system (not shown) for recycling the collected chemical agent.

The elevation bar 3330 may be connected to the collection box 3310 to receive a power from the elevation driver 3340, thereby vertically moving the collection box 3310. If the collection box is provided in plurality, the elevation bar 3330 may be connected to the outermost collection box 3310. The elevation driver 3340 may elevate the collection box 3310 through the elevation bar 3330 to adjust the collection hole 3331, through which the scattered chemical agent is introduced, of the plurality of collection holes 3311.

Hereinafter, the second process chamber 4000 will be described.

The supercritical drying process may be performed in the second process chamber 4000 by using the supercritical fluid. As described above, the process performed in the second process chamber 4000 may include other supercritical processes in addition to the supercritical drying process.

Hereinafter, the second process chamber 4000 according to an embodiment will be described.

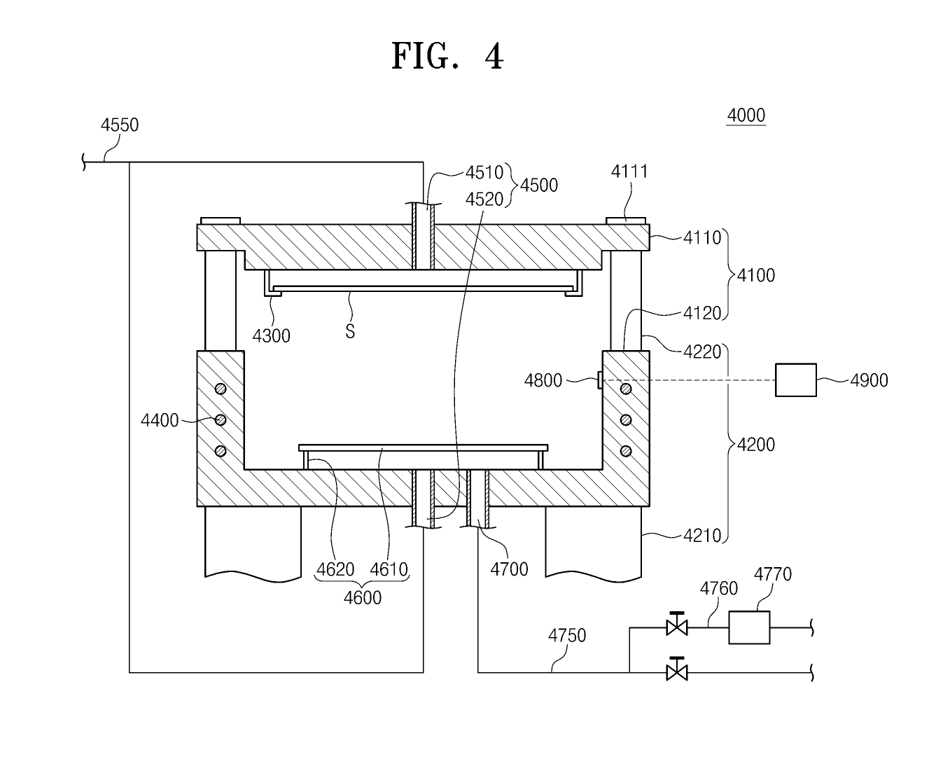

FIG. 4 is a cross-sectional view of the second process chamber 4000 of FIG. 2 according to an embodiment.

Referring to FIG. 4, the second process chamber 4000 may include a housing 4100, an elevation member 4200, a support member 4300, a heating member 4400, a supply port 4500, a blocking member 4600, a pressure meter 4800, and a controller 4900.

The housing 4100 may provide a space in which the supercritical drying process is performed. The housing 4100 may be formed of a material that is capable of enduring a high pressure greater than a critical pressure.

The housing 4100 may include an upper housing 4110 and a lower housing 4120 disposed under the upper housing 4110. That is, the housing 2510 may have a structure which is divided into upper and lower portions.

The upper housing 4110 may be fixed, and the lower housing 4120 may be elevated. When the lower housing 4120 descends and then is spaced from the upper housing 4110, an inner space of the second process chamber 4000 may be opened. Thus, the substrate S may be loaded into or unloaded from the inner space of the second process chamber 4000. Here, the substrate S loaded into the second process chamber 4000 may be in a state in which the organic solvent remains after the organic solvent process is performed in the first process chamber 3000. Also, when the lower housing 4120 ascends and then is closely attached to the upper housing 4110, the inner space of the second process chamber 4000 may be sealed, and the supercritical drying process may be performed in the inner space of the second process chamber 4000. Unlike the above-described example, the lower housing 4120 may be fixed to the housing 4100, and the upper housing 4110 may be elevated.

The elevation member 4200 elevates the lower housing 4120. The elevation member 4200 may include an elevation cylinder 4210 and an elevation rod 4220. The elevation cylinder 4210 is coupled to the lower housing 4120 to generate a vertical driving force, i.e., an elevating force. The elevation cylinder 4210 may endure the high pressure that is above the critical pressure within the second process chamber 4000 while the supercritical drying process is performed. Also, the elevation cylinder 4210 may generate a driving force that is enough to closely attach the upper and lower housings 4110 and 4120 to each other to seal the inside of the second process chamber 4000. The elevation rod 4220 has one end inserted into the elevation cylinder 4210 and the other end extending upward and coupled to the upper housing 4110. Due to the above-described structure, when the driving force is generated in the elevation cylinder 4210, the elevation cylinder 4210 and the elevation rod 4220 may relatively ascend to allow the lower housing 4120 coupled to the elevation cylinder 4210 to ascend. Also, while the lower housing 4120 ascends by the elevation cylinder 4210, the elevation rod 4220 may prevent the upper and lower housings 4110 and 4120 from horizontally moving and may guide an elevation direction to prevent the upper and lower housings 4110 and 4120 from being separated from its regular positions.

The support member 4300 supports the substrate S between the upper housing 4110 and the lower housing 4120. The support member 4300 may be disposed on a bottom surface of the upper housing 4110 to extend directly downward. Also, the support member 4300 may be bent from a lower end of the upper housing 4110 in a direction perpendicular to a horizontal direction. Thus, the support member 4300 may support an edge region of the substrate S. As described above, since the support member 4300 contacts the edge region of the substrate S to support the substrate S, the supercritical drying process may be performed on the entire area of the top surface of the substrate S and most areas of a bottom surface of the substrate S. Here, the top surface of the substrate S may be a pattern surface, and the bottom surface of the substrate S may be a non-pattern surface. Also, since the fixed upper housing 4110 is provided, the support member 4300 may relatively stably support the substrate S while the lower housing 4120 is elevated.

A horizontal adjustment member 4111 may be disposed on the upper housing 4110 on which the support member 4300 is disposed. The horizontal adjustment member 4111 may adjust horizontality of the upper housing 4110. When the upper housing 4110 is adjusted in horizontality, the substrate S seated on the support member 4300 disposed in the upper housing 4110 may be adjusted in horizontality. When the substrate S is sloped in the supercritical drying process, the organic solvent remaining on the substrate S may flow along a sloop to cause a phenomenon in which a specific portion of the substrate S is not dried or is overdried, thereby damaging the substrate S. The horizontal adjustment member 4111 may adjust horizontality of the substrate S to prevent the above-described phenomenon from occurring. Of course, when the upper housing 4110 ascends, and the lower housing 4120 is fixed, or when the support member 4300 is disposed in the lower housing 4120, the horizontal adjustment member 4111 may be provided in the lower housing 4120.

The heating member 4400 may heat the inside of the second process chamber 4000. The heating member 4400 may heat the supercritical fluid supplied into the second process chamber 4000 at a temperature greater than a critical temperature to maintain the supercritical fluid to a supercritical fluid phase or change again into the supercritical fluid if the supercritical fluid is liquefied. The heating member 4400 may be embedded in at least one wall of the upper and lower housings 4110 and 4120. For example, the heating member 4400 may be provided as a heater for receiving a power from the outside to generate heat.

The supply port 4500 supplies the supercritical fluid to the second process chamber 4000. The supply port 4500 may be connected to a supply line 4550 for supplying the supercritical fluid. Here, a valve for adjusting a flow rate of the supercritical fluid supplied from the supply line 4550 may be disposed in the supply port 4500.

The supply port 4500 may include an upper supply port 4510 and a lower supply port 4520. The upper supply port 4510 may be provided in the upper housing 4110 to supply the supercritical fluid onto the top surface of the substrate S that is supported by the support member 4300. The lower supply port 4520 may be provided in the lower housing 4120 to supply the supercritical fluid onto the bottom surface of the substrate S that is supported by the support member 4300.

The supply ports 4500 may spray the supercritical fluid onto a central area of the substrate S. For example, the upper supply port 4510 may be disposed at a position that is disposed directly above a center of the top surface of the substrate S supported by the support member 4300. Also, the lower supply port 4520 maybe disposed at a position that is disposed directly below the center of the substrate S supported by the support member 4300. Thus, the supercritical fluid sprayed into the supply port 4500 may reach the central area of the substrate S and then be spread to the edge area of the substrate S. As a result, the supercritical fluid may be uniformly supplied onto the entire area of the substrate S.

In the upper and lower supply ports 4510 and 4520, the lower supply port 4520 may supply the supercritical fluid, and then the upper supply port 4510 may supply the supercritical fluid. Since the supercritical drying process is performed in a state where an internal pressure of the second process chamber 4000 is less than the critical pressure, the supercritical fluid supplied into the second process chamber 4000 may be liquefied. Thus, when the supercritical fluid is supplied into the upper supply port 4510 during an initial supercritical drying process, the supercritical fluid may be liquefied to drop onto the substrate S by the gravity, thereby damaging the substrate S. When the supercritical fluid is supplied into the second process chamber 4000 through the lower supply port 4520 to allow the internal pressure of the second process chamber 4000 to reach the supercritical pressure, the upper supply port 4510 may start the supply of the supercritical fluid to liquefy the supercritical fluid, thereby preventing the supercritical fluid from dropping onto the substrate S.

The blocking member 4600 may prevent the supercritical fluid supplied through the supply port 4500 from being directly sprayed onto the substrate S. The blocking member 4600 may include a blocking plate 4610 and a support 4620.

The blocking plate 4610 is disposed between the supply port 4500 and the substrate S supported by the support member 4300. For example, the blocking plate 4610 may be disposed between the lower supply port 4520 and the support member 4300 and be disposed under the substrate S. The blocking plate 4610 may prevent the supercritical fluid supplied through the lower supply port 4520 from being directly sprayed onto the bottom surface of the substrate S.

The blocking plate 4610 may have a radius similar to or greater than that of the substrate S. In this case, the blocking plate 4610 may completely prevent the supercritical fluid from being directly sprayed onto the substrate S. Also, the blocking plate 4610 may have a radius less than that of the substrate S. In this case, the direct spraying of the supercritical fluid onto the substrate S may be prevented, and also, the velocity of the supercritical fluid may be minimized. Thus, the supercritical fluid may more easily reach the substrate S to effectively perform the supercritical drying process on the substrate S.

The support 4620 supports the blocking plate 4610. That is, the blocking plate 4610 may be disposed on an end of the support 4620. The support 4620 may extend directly upward from the bottom surface of the housing 4100. The support 4620 and the blocking plate 4610 may be disposed so that the blocking plate 4610 is simply placed on the support 4620 by the gravity without using separate coupling. When the support 4620 and the blocking plate 4610 are coupled to each other by using a coupling unit such as a nut or bolt, the supercritical fluid having high penetrability may be penetrated between the support 4620 and the blocking plate 4610 to generate contaminants. Alternatively, the support 4620 and the blocking plate 4610 may be integrated with each other.

When the supercritical fluid is supplied through the lower supply port 4520 during the initial supercritical drying process, since an internal pressure of the housing 4500 is low, the supplied supercritical fluid may be sprayed at a high speed. When the supercritical fluid sprayed at the high speed directly reaches the substrate S, a leaning phenomenon in which a portion of the substrate S onto which the supercritical fluid is directly sprayed is bent by a physical pressure of the supercritical fluid may occur. Also, the substrate may be shaken by the spraying force of the supercritical fluid. Here, the organic solve remaining on the substrate S may flow to damage a circuit pattern of the substrate S.

Thus, the blocking plate 4610 disposed between the lower supply port 4520 and the support member 4300 may prevent the supercritical fluid from being directly sprayed onto the substrate S to prevent the substrate S from being damaged by the physical force of the supercritical fluid. However, the blocking plate 4610 is not limited in position between the lower supply port 4520 and the support member 4300.

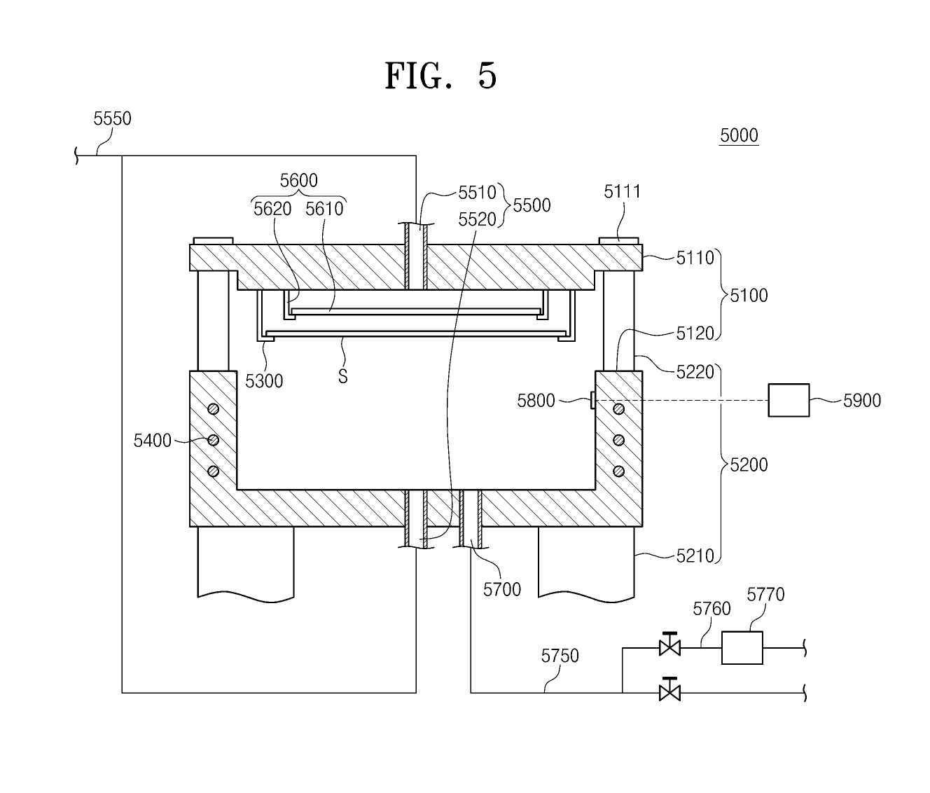

FIG. 5 is a view illustrating a modified example of the second process chamber of FIG. 4.

Referring to FIG. 5, a blocking plate 5610 may be disposed between an upper supply port 5510 and a substrate S seated by a support member 5300. Here, a support 5620 extends directly upward from a bottom surface of an upper housing 5110. A lower end of the support 5620 may be horizontally bent. Due to the above-described structure, the support 5620 may support the blocking plate 5610 by the gravity without using a separate coupling unit.

However, when the blocking plate 5610 is disposed on a path through which a supercritical fluid sprayed from a supply port reaches the substrate S, since the supercritical fluid reaching the substrate S is deteriorated in efficiency, the blocking plate 5610 may be installed in consideration of a degree of damage of the substrate S by the supercritical fluid and a degree of drying of the substrate onto which the supercritical fluid is transferred.

Particularly, when a plurality of supply ports are provided in the second process chamber 4000, the blocking plate 5610 may be disposed on a moving path through which the supercritical fluid sprayed from the supply ports for supplying the supercritical fluid is directly sprayed onto the substrate S during an initial supercritical drying process.

An exhaust port 4700 exhausts the supercritical fluid from the second process chamber 4000. The exhaust port 4700 is connected to a first exhaust line 4750. The first exhaust line 4750 exhausts the supercritical fluid. The supercritical fluid exhausted through the first exhaust line 4750 may be discharged into air or supplied into a supercritical fluid recycling system (not shown). Here, a valve for adjusting a flow rate of the supercritical fluid exhausted into the exhaust line 4750 may be disposed in the exhaust port 4700.

A second exhaust line 4760 is branched from the first exhaust line 4750. Here, the second exhaust line 4760 may include a decompression pump 4770. Due to the decompression pump 4770, even though an internal pressure of the second process chamber 4000 reaches the atmospheric pressure, the internal pressure of the second process chamber 4000 may be further drop.

An exhaust port 4700 may be disposed on a lower housing 4120. In the late supercritical drying process, the supercritical fluid may be exhausted from the second process chamber 4000 and thus be decompressed in internal pressure below a critical pressure. Thus, the supercritical fluid may be liquefied. The liquefied supercritical fluid may be discharged through the exhaust port 4700 disposed on the lower housing 4120 by the gravity.

A pressure meter 4800 is disposed in a housing 4100. For example, referring to FIG. 4, the pressure meter 4800 may be disposed on one sidewall of the lower housing 4120. The pressure meter 4800 measures a pressure within the second process chamber 4000. The pressure meter 4800 transmits the measured pressure value to a controller 4900.

The controller 4900 determines an opening time of the second process chamber 4000. The controller 4900 receives the pressure value from the pressure meter 4800. The controller 4900 determines the opening time of the second process chamber 4000 according to the pressure value. In the process of treating the substrate by using the supercritical fluid, the second process chamber 4000 may have a very high internal pressure. Thus, after the process is finished, the second process chamber 4000 has to be opened after the internal pressure of the second process chamber 4000 reaches an opening pressure P0. Here, if the second process chamber 4000 is immediately opened after the internal pressure of the second process chamber 4000 reaches the opening pressure P0, the second process chamber 4000 may be opened in a state where residues of carbon dioxide and an organic solvent within the second process chamber 4000 are not sufficiently exhausted. Thus, the residues of the carbon dioxide and organic solvent may be exhausted to the outside of the second process chamber 4000 through a door. The residues of the carbon dioxide and organic solvent may contaminate external environments of the second process chamber 4000 and act as particles to affect following processes. Thus, the controller 4900 may adjust the opening time of the second process chamber 4000. The controller 4900 may open the second process chamber 4000 when a set condition elapses from a time at which the internal pressure of the second process chamber 4000 reaches the opening pressure P₀. The opening pressure P₀ may be preset. For example, the opening pressure P₀ may be the atmospheric pressure. Also, the controller 4900 may control the second process chamber 4000 so that the supercritical fluid within the second process chamber 4000 is discharged into the decompression pump 4770 after the internal pressure of the second process chamber 4000 reaches the opening pressure P₀. The controller 4900 may adjust the opening time of the second process chamber 4000 to allow the residues of the carbon dioxide and organic solvent within the second process chamber 4000 to be sufficiently exhausted.

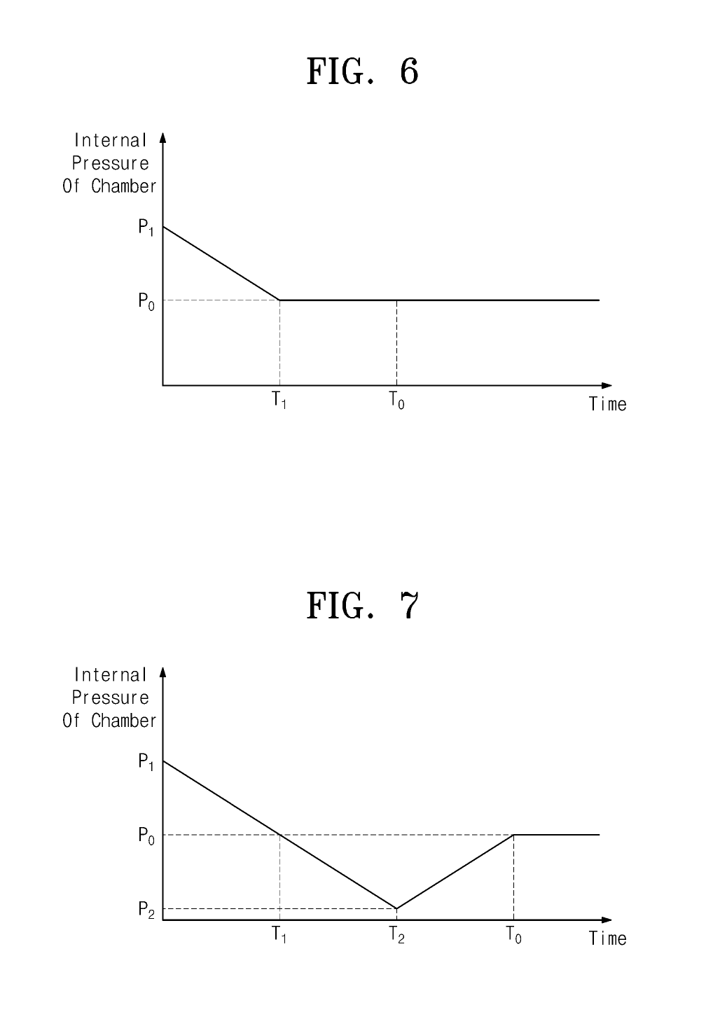

FIG. 6 is a graph illustrating an example of the set condition. FIG. 7 is a graph illustrating another example of the set condition. The set condition may be a state in which a set time elapses from a time at which the internal pressure of the second process chamber 4000 reaches the opening pressure P₀. Here, the set time may range from about 1 second to about 60 seconds. On the other hand, the set time may be a state in which the internal pressure of the second process chamber 4000 rises again up to the opening pressure P₀ after the internal pressure of the second process chamber 4000 drops down up to a pressure P₂ less than the opening pressure P₀. During this time, the carbon dioxide and organic solvent within the second process chamber 4000 may be discharged to the outside through a discharge port. Thus, generation of organic particles within the second process chamber 4000 may be minimized.

Although the substrate treating apparatus 100 supplies the supercritical fluid onto the substrate S to treat the substrate S, the present invention is not limited thereto. For example, the process performed by the substrate treating process 100 may not be limited to the supercritical process. Thus, another process fluid instead of the supercritical fluid may be supplied into the supply port of the second process chamber 4000 of the substrate treating apparatus 100 to treat the substrate S. In this case, an organic solvent or other various components such as gases, plasma gases, and inert gases instead of the supercritical fluid may be used as the process fluid.

Also, the substrate treating apparatus 100 may further include a controller for controlling the constitutions. For example, the controller may control a heating member 4400 to adjust an inner temperature of the housing 4100. For another example, the controller may control the nozzle member 2320, the supply line 4550, or the exhaust line 4750 to adjust a flow rate of the chemical agent or supercritical fluid. For another example, the controller may control the elevation member 4200 or a pressing member to open or close the housing 4100. For another example, the controller may control the supply ports 4100 and 4120 so that, when one of the upper supply port 4110 and the lower supply port 4120 starts the supply of the supercritical fluid to allow the internal pressure of the second process chamber 4000 to reach a preset pressure, the other supply port starts the supply of the supercritical fluid.

The controller may be implemented through a computer or a device similar to the computer by using hardware, software, and a combination thereof.

In the hardware implementation, the controller may be implemented by using application specific integrated circuits (ASICs), digital signal processors (DSPs), digital signal processing devices (DSPDs), programmable logic devices (PLDs), field programmable gate arrays (FPGAs), processors, controllers, micro-controllers, microprocessors, or electrical devices for performing similar functions.

In the software implementation, the controller may be implemented by a software code or software application that is written with at least one program language. The software may be executed by the controller that is implemented by the hardware. Also, the software may be transmitted into the above-described hardware from an external device such as a server and then be installed.

Hereinafter, a substrate treating method using a substrate treating apparatus 100 according to the present invention will be described. However, since this is merely an example for convenience of description, the substrate treating method may be performed by using other apparatuses that are equal or similar to the above-described substrate treating apparatus 100 in addition to the substrate treating apparatus 100. Also, the substrate treating method according to the present invention may be stored in a computer-readable recording medium in the form of code or program.

Hereinafter, the substrate treating method according to an embodiment will be described. The substrate treating method according to an embodiment relates to a supercritical drying process that is performed in a second process chamber.

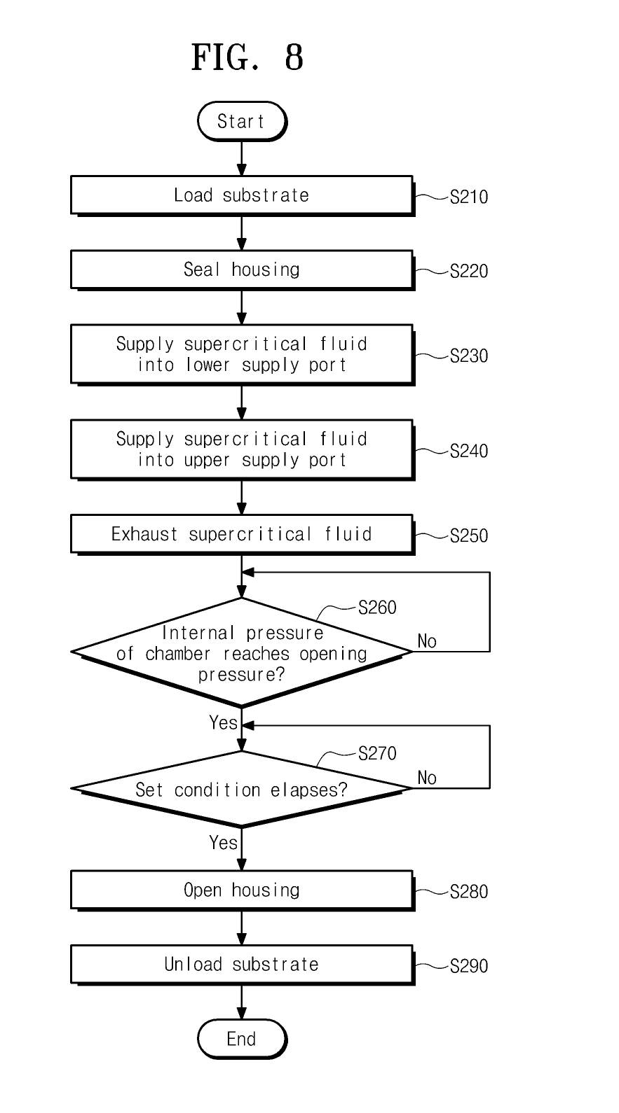

FIG. 8 is a flowchart of a substrate treating method according to an embodiment. The substrate treating method according to an embodiment includes a process (S210) of loading a substrate S into a second process chamber 4000, a process (S220) of sealing a housing 4100, a process (S230) of supplying a supercritical fluid into a lower supply port 4520, a process (S240) of supplying the supercritical fluid into an upper supply part 4510, a process (S250) of exhausting the supercritical fluid, a process (S260) of allowing an internal pressure of the second process chamber 4000 to reach an opening pressure P₀, a process (S270) of allowing a set condition to elapse, a process (S270) of opening the housing 4100, and a process (S280) of unloading the substrate S from the second process chamber 4000. Hereinafter, each of the above-described processes will be described.

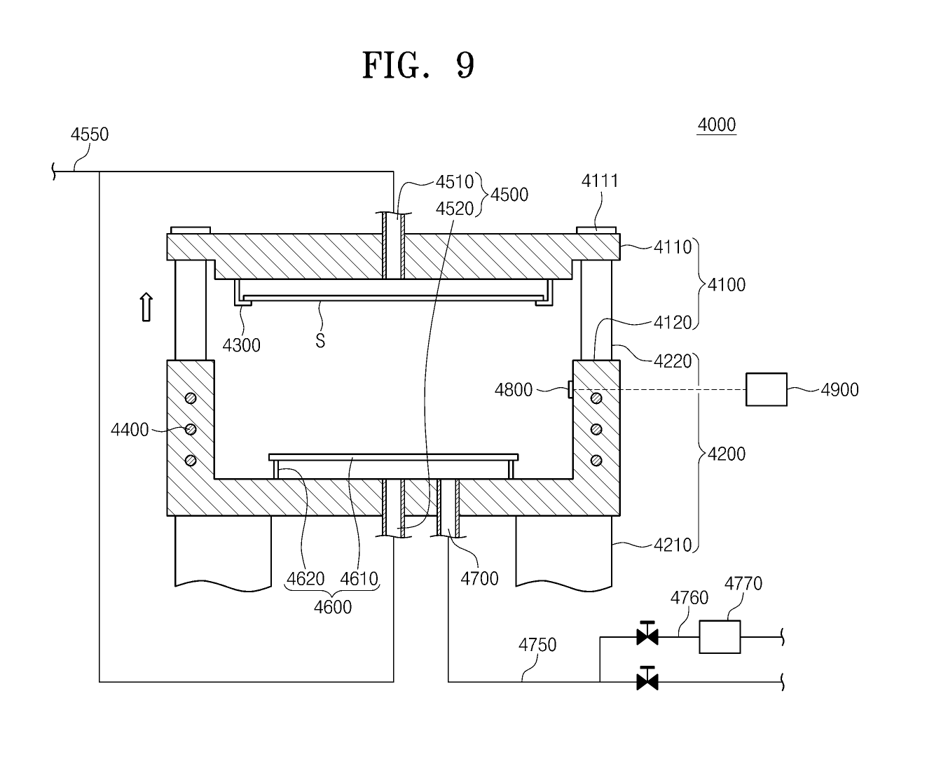

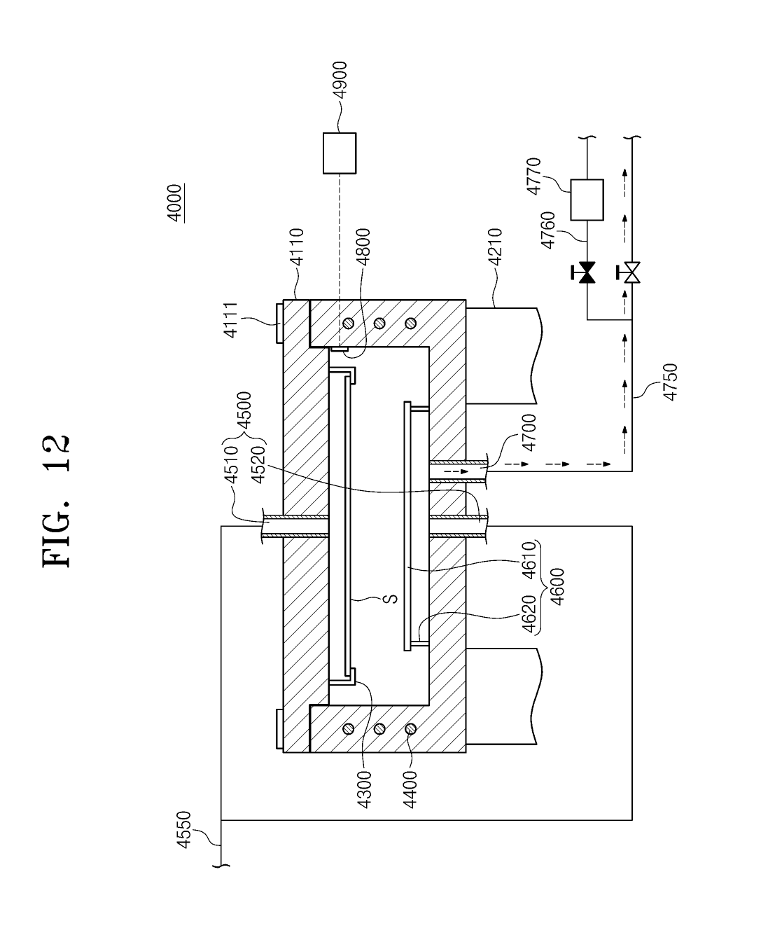

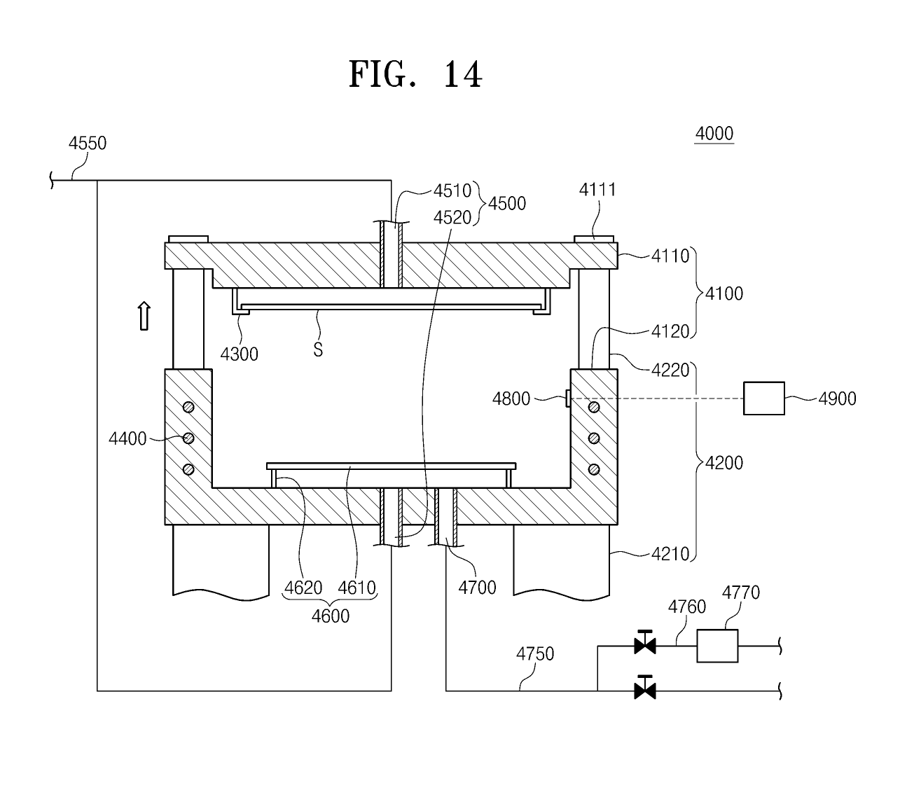

FIGS. 9 to 14 are views illustrating an operation process according to the substrate treating method of FIG. 8. Hereinafter, the substrate treating process will be described with reference to FIGS. 9 and 14. An arrow represents a flow of a fluid. A valve of which the inside is filled represents a closed valve, and a valve of which the inside is empty represents an opened valve.

In operation S210, a substrate S is loaded into a second process chamber 4000. The substrate S is placed on a support member 4300 of the second process chamber 4000. A transfer robot 2210 may take the substrate S, on which an organic solvent remains, out for a first process chamber 3000 to place the substrate S on the support member 4300.

Referring to FIG. 9, in case of a second process chamber 4000 including upper and lower chambers, a housing 4100 is separated into an upper housing 4110 and a lower housing 4120 and thus is opened. The transfer robot 2210 loads the substrate S on the support member 4300.

In case of a second process chamber 400 having a slide structure in which a door moves horizontally, the transfer robot 2210 loads the substrate S on the support member 4300 in a state where the door 4130 is spaced apart from an opening. When the substrate S is seated, the door 4130 may move into the housing 4100 to load the substrate S into the second process chamber 4000.

In case of a second process chamber 4000 having a structure in which a door plate 4131 moves by a door driver 4132, the transfer robot 2210 may move into the housing 4100 to seat the substrate S on the support member 4300.

In operation S220, when the substrate S is loaded, the housing 4100 is sealed.

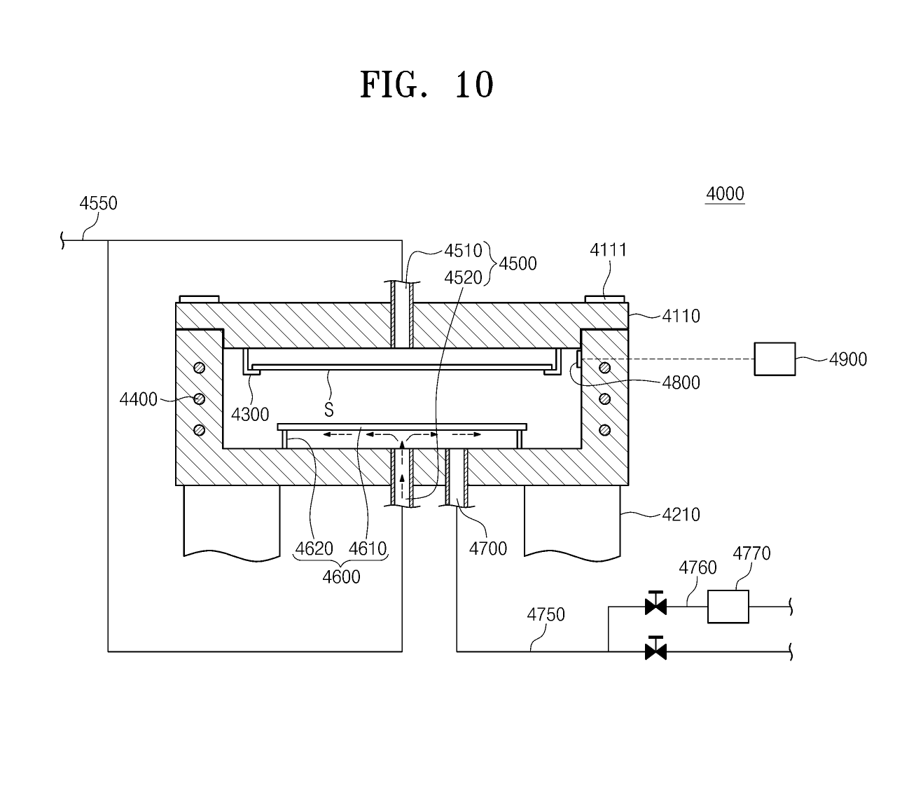

Referring to FIG. 10, in case of the second process chamber 4000 including upper and lower chambers, an elevation member 4200 may lift a lower housing 4120 to allow the lower housing 4120 to be closely attached to an upper housing 4110 to seal the housing 4100, i.e., the second process chamber 4000.

In case of a second process chamber 4000 having a slide structure, a pressing member 4800 may horizontally move a door 4130 to allow the door 4130 to be closely attached to an opening, thereby sealing the housing 4100. Alternatively, a door driver 4132 may operate to allow a door plate 4131 to close the opening.

When the second process chamber 4000 is sealed, a supercritical fluid is supplied into a lower supply port 4520 in operation S230. When the supercritical fluid is initially introduced, an internal pressure of the housing 4100 may be in a state the internal pressure of the housing 4100 is below a critical pressure. Thus, the supercritical fluid may be liquefied. When the supercritical fluid is supplied onto the substrate S, the supercritical fluid may be liquefied to drop onto the substrate S. Thus, the substrate S may be damaged. As a result, the supercritical fluid may be supplied through the lower supply port 4520, and then, be supplied through the upper supply port 4510. In this process, a heating member 4300 may heat the inside of the housing 4100.

A blocking plate 5610 blocks the direct spraying of the supercritical fluid onto the substrate S. The blocking plate 4610 disposed between the lower supply port 4520 and the support member 4300 may prevent the supercritical fluid sprayed through the lower supply port 4520 from being directly sprayed on the substrate S. Thus, since a physical force of the supercritical fluid is not applied to the substrate S, leaning may not occur on the substrate S. The supercritical fluid sprayed directly upward from the lower supply port 4520 may collide with the blocking plate 4610 to move horizontally. Then, the supercritical fluid may detour the blocking plate 4610 and then be supplied onto the substrate S.

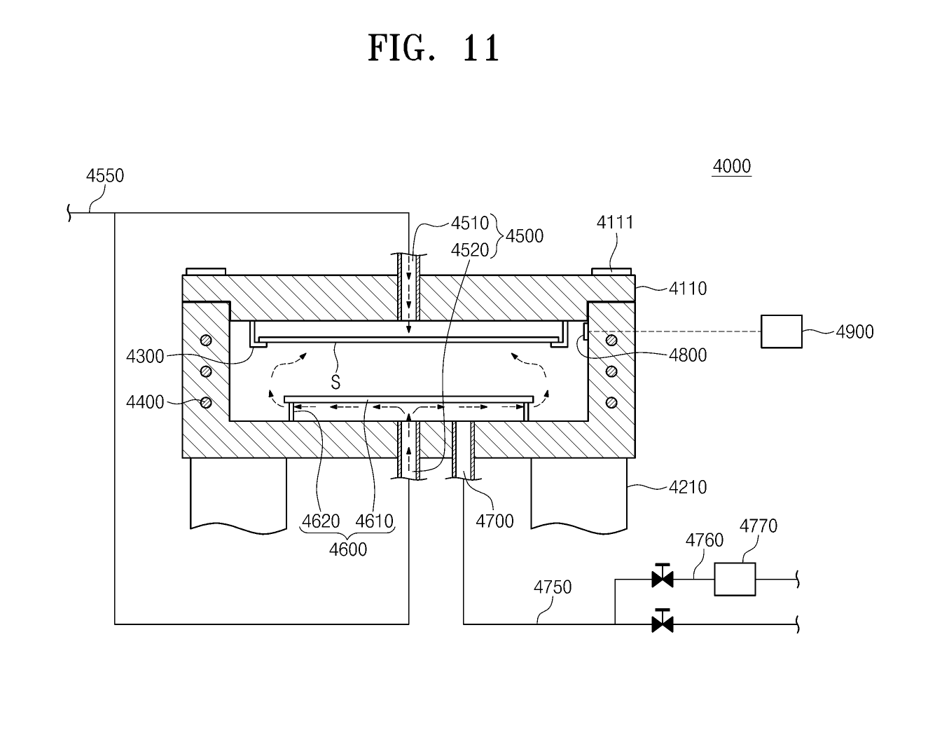

Referring to FIG. 11, in operation S240, the supercritical fluid is supplied into the upper supply port 4510. When the supercritical fluid is continuously introduced through the lower supply port 4510, the internal pressure of the housing 4100 may increase. When the inside of the housing 4100 is heated by the heating member 4200, an inner temperature of the housing 4100 may rise above a critical temperature to form a supercritical atmosphere within the housing 4100. The upper supply port 4510 may state the supply of the supercritical fluid when the supercritical atmosphere is formed within the housing 4100. That is, a controller may supply the supercritical fluid through the upper supply port 4510 when the internal pressure of the housing 4100 is above the critical pressure.

Here, the supercritical fluid sprayed through the upper supply port 4510 may not be blocked by the blocking plate 4610. Since the internal pressure of the housing 4100 exceeds the critical pressure already, the supercritical fluid supplied into the supply port may be significantly reduced in flow rate within the housing 4100. Thus, a flow rate that may cause the leaning phenomenon when the supercritical fluid reaches the substrate S may be lost.

Since the supercritical fluid sprayed through the upper supply port 4510 is not blocked by the blocking member 4600, a top surface of the substrate S may be well dried. In general, since the substrate S has the top surface to be patterned, the blocking plate 4610 may not be disposed between the upper supply port 4510 and the support member 4300 to well transfer the supercritical fluid onto the substrate S, thereby effectively drying an organic solvent existing between the circuit patterns of the substrate S. Alternatively, the blocking plate 4610 may be disposed between the upper supply port 4510 and the support member 4300 to directly spray the supercritical fluid to be sprayed onto the top surface of the substrate S onto the substrate S in overall consideration of the process environments.

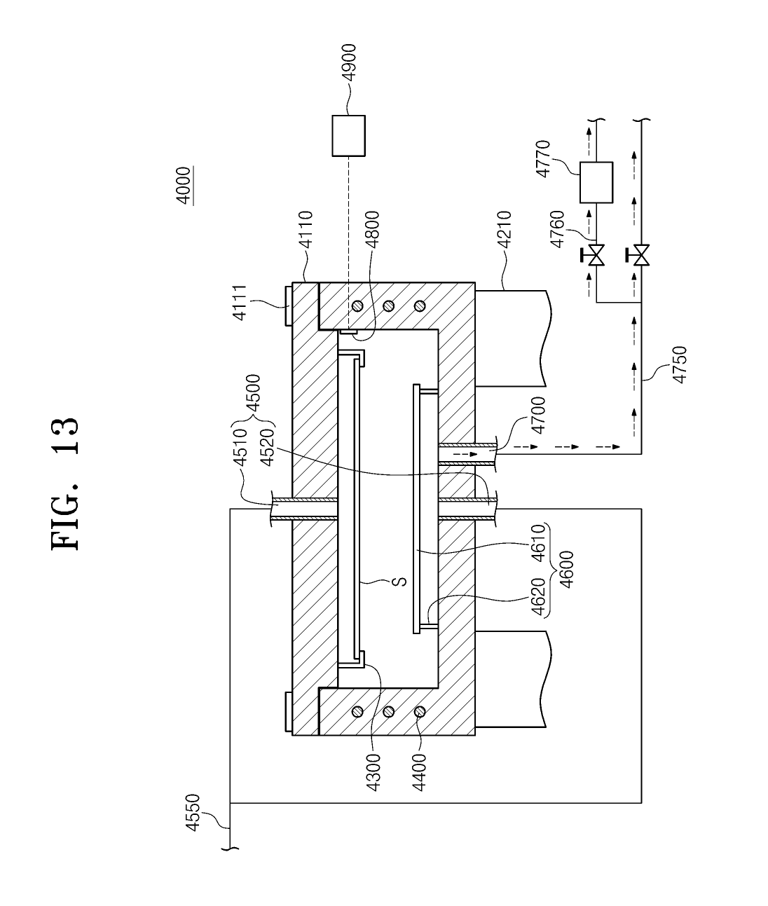

In operation S250, when the organic solvent remaining on the substrate S is dissolved by the supercritical fluid to sufficiently dry the substrate S, the supercritical fluid is exhausted. The exhaust port 4700 exhausts the supercritical fluid from the second process chamber 4000. The supercritical fluid may be exhausted through a first exhaust line 4750. In operations S260 and S270, when the internal pressure of the second process chamber 4000 reaches an opening pressure P₀, the controller 4900 opens the second process chamber 4000 after a set condition elapses. For example, the controller 4900 may open the second process chamber 4000 after the set condition elapses from a time at which the internal pressure of the second process chamber 4000 reaches the opening pressure P₀. The opening pressure P₀ may be preset. For example, the opening pressure P₀ may be the atmospheric pressure. Here, the set time may range from about 1 second to about 60 seconds. On the other hand, the controller 4900 may open the second process chamber 4000 when the internal pressure of the second process chamber 4000 rises again up to the opening pressure P₀ after the internal pressure of the second process chamber 4000 drops down up to a pressure P₂ less than the opening pressure P₀. During this time, the carbon dioxide and organic solvent within the second process chamber 4000 may be discharged to the outside through the discharge port. Thus, generation of organic particles within the second process chamber 4000 may be minimized. Here, as illustrated in FIG. 13, the controller 4900 may control the second process chamber 4000 so that the supercritical fluid within the second process chamber 4000 is discharged into a decompression pump 4770 after the internal pressure of the second process chamber 4000 reaches the opening pressure P₀. The controller 4900 may control each of the supply line 4550 and the exhaust line 4750 to adjust a flow rate of the supercritical fluid. The supercritical fluid exhausted through the exhaust line 4750 may be discharged into air or supplied into a supercritical fluid recycling system (not shown).

In operation S280, when the set condition elapses, the controller 4900 opens the housing 4100. Referring to FIG. 14, the lower housing 4120 may descend by the elevation member 4200 to open the housing 4100.

In case of a second process chamber 400 having a slide structure in which a door 4130 moves horizontally, the pressing member may space the door 4130 from the opening to open the housing 4100. In case of a second process chamber 4000 having a structure in which a door plate 4131 moves by a door driver 4132, the door driver 4132 may move the door plate 4131 to open the housing 4100.

In operation S290, the substrate S is unloaded from the second process chamber 4000. When the housing 4100 is opened, the transfer robot 2210 may unload the substrate S from the second process chamber 4000.

According to the embodiments of the present invention, the substrate treating apparatus that is capable of minimizing the back-contamination within the housing may be provided.

The object of the present invention is not limited to the aforesaid, but other objects not described herein will be clearly understood by those skilled in the art from descriptions below.

The present invention has been explained in detail by using the above-described embodiments; however, it is obvious that for persons skilled in the art, the present invention is not limited to the embodiments explained herein.

Thus, the present invention can be implemented as a corrected and modified mode without departing the gist and the scope of the present invention defined by the claims.

Also, the scope of the invention is defined not by the detailed description of the invention but by the appended claims, and all differences within the scope will be construed as being included in the present invention.

What is claimed is:

1. A substrate treating apparatus comprising:
a process chamber in which a predetermined process is performed on a substrate;
a pressure meter measuring a pressure within the process chamber; and
a controller receiving the measured pressure value from the pressure meter to determine an opening time of the process chamber,
wherein the controller opens the process chamber when a set condition elapses from a time at which the pressure within the process chamber reaches a preset opening pressure.

2. The substrate treating apparatus of claim 1, wherein the predetermined process comprises a process for treating the substrate by using a supercritical fluid, and
the set condition is a state in which a set time elapses from the time at which the pressure within the process chamber reaches the preset opening pressure.

3. The substrate treating apparatus of claim 2, wherein the set time ranges from about 1 second to about 60 seconds.

4. The substrate treating apparatus of claim 3, wherein the opening pressure is the same as an atmospheric pressure.

5. The substrate treating apparatus of claim 4, further comprising a first exhaust line for exhausting a gas within the process chamber to the outside of the process chamber.

6. The substrate treating apparatus of claim 5, further comprising:
a second exhaust line branched from the first exhaust line; and
a decompression pump disposed on the second exhaust line,
wherein the controller controls the decompression pump to discharge the gas within the process chamber from a time at which the pressure within the process chamber reaches the preset opening pressure.

7. The substrate treating apparatus of claim 6, wherein the controller opens the process chamber when the pressure within the process chamber rises again up to the preset opening pressure after the pressure within the process chamber drops down up to a pressure that is less than the preset opening pressure.

8. The substrate treating apparatus of claim 1, wherein the predetermined process comprises a process for treating the substrate by using a supercritical fluid, and
the set condition is a state in which the pressure within the process chamber rises again up to the preset opening pressure after the pressure within the process chamber drops down up to a pressure that is less than the preset opening pressure.

9. The substrate treating apparatus of claim 8, wherein the opening pressure is the same as an atmospheric pressure.

10. The substrate treating apparatus of claim 9, further comprising a first exhaust line for exhausting a gas within the process chamber to the outside of the process chamber.

11. The substrate treating apparatus of claim 10, further comprising:
a second exhaust line branched from the first exhaust line; and
a decompression pump disposed on the second exhaust line,
wherein the controller controls the decompression pump to discharge the gas within the process chamber from a time at which the pressure within the process chamber reaches the preset opening pressure.

12. A substrate treating method comprising:
opening a process chamber after a predetermined process is performed in the process chamber,
wherein a pressure within the process chamber is measured to open the process chamber after a set condition elapses from a time at which the pressure within the process chamber reaches a preset opening pressure.

13. The substrate treating method of claim 12, wherein the predetermined process comprises a process for treating the substrate by using a supercritical fluid, and
the set condition is a state in which a set time elapses from the time at which the pressure within the process chamber reaches the preset opening pressure.

14. The substrate treating method of claim 13, wherein the set time ranges from about 1 second to about 60 seconds.

15. The substrate treating method of claim 14, wherein the opening pressure is the same as an atmospheric pressure.

16. The substrate treating method of claim 15, wherein, when the pressure within the process chamber rises again up to the preset opening pressure after the pressure within the process chamber drops down up to a pressure that is less than the preset opening pressure, the process chamber is opened.

17. The substrate treating method of claim 12, wherein the predetermined process comprises a process for treating the substrate by using a supercritical fluid, and
the set condition is a state in which the pressure within the process chamber rises again up to the preset opening pressure after the pressure within the process chamber drops down up to a pressure that is less than the preset opening pressure.

18. The substrate treating method of claim 17, wherein the opening pressure is the same as an atmospheric pressure.
